(19) United States
(12) Patent Application Publication
(10) Pub. No.: US 2022/0255295 A1
(43) Pub. Date: Aug. 11, 2022

(54) HIGH-POWER TUNABLE LASER ON SILICON PHOTONICS PLATFORM

(71) Applicant: INPHI CORPORATION, San Jose, CA (US)

(72) Inventors: Xiaoguang HE, Diamond Bar, CA (US); Radhakrishnan L. NAGARAJAN, San Jose, CA (US)

(21) Appl. No.: 17/168,916

(22) Filed: Feb. 5, 2021

(51) Int. Cl. H01S 5/068; H01S 5/343; H01S 5/028; H01S 5/10; H01S 5/0234

(52) U.S. Cl. CPC H01S 5/068; H01S 5/343; H01S 5/0234; H01S 5/101; H01S 5/1028; H01S 5/028

(57) ABSTRACT

A high-power tunable laser includes a gain medium configured to emit light and amplify light intensity. The gain medium has a length equal to or greater than 1.5 mm between a backend and a frontend configured to be an output port for outputting light with amplified intensity. The high-power tunable laser further includes a wavelength tuner optically coupled to the backend to receive light from the gain medium and configured to tune wavelength for the light and have a high-reflectivity reflector to reflect the light with a tuned wavelength back to the gain medium.

### BACKGROUND OF THE INVENTION

The present invention relates to optical communication techniques. More particularly, the present invention provides a high-power tunable laser based on silicon photonics platform.

Over the last few decades, the use of communication networks exploded. In the early days Internet, popular applications were limited to emails, bulletin board, and mostly informational and text-based web page surfing, and the amount of data transferred was usually relatively small. Today, Internet and mobile applications demand a huge amount of bandwidth for transferring photo, video, music, and other multimedia files. For example, a social network like Facebook processes more than 500 TB of data daily. With such high demands on data and data transfer, existing data communication systems need to be improved to address these needs.

A wavelength tunable laser source is used to generate various wavelength emitted from a single wavelength light source. Commercial and scientific interest in tunable lasers continues to grow rapidly because of their potential application in optical components testing, fiber optic sensors, and wavelength division multiplexing (WDM) transmission systems Semiconductor optical amplifier in silicon photonics platform have been implemented for many applications of optical communication. For example, a wavelength tunable laser consisting of a reflective semiconductor optical amplifier (RSOA) based ring tuner has been used to boost laser output power for wide-band optical communication. However, RSOA coupled into tunable laser has extra coupling loss that reduces the power efficiency of the laser. Technical challenges exist for developing a RSOA gain chip for high-power operation with high efficiency at elevated temperature in wide-band high-speed data communication application. Therefore, improved techniques are desired.

### BRIEF SUMMARY OF THE INVENTION

The present invention relates to optical telecommunication techniques. One aspect of the present invention provides a high-power tunable laser based on silicon photonics platform. More particularly, the present invention provides a wavelength tunable laser including a reflective semiconductor optical amplifier (RSOA) based gain medium with its backend coupled to a resonant ring tuner with high reflectivity to produce high saturation power at elevated temperature for high-speed data communication application, though other applications are possible.

In an embodiment, the present invention provides a high-power tunable laser. The high-power tunable laser includes a gain medium configured to emit light and amplify light intensity. The gain medium has a length equal to or greater than 1.5 mm between a backend and a frontend configured to be an output port for outputting light with amplified intensity. Additionally, the high-power tunable laser includes a wavelength tuner optically coupled to the backend to receive light from the gain medium and configured to tune wavelength for the light and have a high-reflectivity reflector to reflect the light with a tuned wavelength back to the gain medium.

In an alternative embodiment, the present invention provides a high-power tunable laser based on silicon photonics platform. The high-power tunable laser includes a silicon substrate. Additionally, the high-power tunable laser includes a semiconductor gain chip flip-mounted on the silicon substrate. The semiconductor gain chip includes a linear gain medium having a length of at least 1.5 mm between a frontend with low-reflectivity and a backend with anti-reflective characteristics and is configured to emit light and amplify light intensity before outputting the light with amplified intensity through the frontend. Furthermore, the high-power tunable laser includes a resonant ring tuner including a pair of rings with different diameters and a reflector all made by wire waveguide built in the silicon substrate and being configured to couple to the backend with anti-reflective characteristics to receive light from the linear gain medium and tune wavelength of the light before reflecting to the linear gain medium substantially by the reflector.

The present invention achieves these benefits and others in the context of known technology of semiconductor optical amplifier for tunable laser based on silicon photonics platform. However, a further understanding of the nature and advantages of the present invention may be realized by reference to the latter portions of the specification and attached drawings.

### BRIEF DESCRIPTION OF THE DRAWINGS

The following diagrams are merely examples, which should not unduly limit the scope of the claims herein. One of ordinary skill in the art would recognize many other variations, modifications, and alternatives. It is also understood that the examples and embodiments described herein are for illustrative purposes only and that various modifications or changes in light thereof will be suggested to persons skilled in the art and are to be included within the spirit and purview of this process and scope of the appended claims.

FIG. 1 is a schematic diagram of a tunable laser device having a gain medium cavity including a backend-coupled wavelength tuner according to an embodiment of the present invention.

FIG. 2 is a schematic diagram of a tunable laser device having a RSOA-based gain medium cavity with high reflectivity achieved through a backend-coupled resonant ring tuner according to an embodiment of the present invention.

FIG. 3 is a schematic diagram of an alternate tunable laser device having a RSOA-based gain medium with a frontend-coupled resonant ring tuner.

FIG. 4 is an exemplary plot of light output power of the tunable laser device of FIG. 2 with different frontend reflectivity according to an embodiment of the present invention.

FIG. 5 is an exemplary plot of laser spectrum produced by the tunable laser device of FIG. 2 for wavelength around 1550 nm according to an embodiment of the present invention.

### DETAILED DESCRIPTION OF THE INVENTION

The present invention relates to optical telecommunication techniques. One aspect of the present invention provides a high-power tunable laser based on silicon photonics platform. More particularly, the present invention provides a wavelength tunable laser including a reflective semiconductor optical amplifier (RSOA) based gain medium with its backend coupled to a resonant ring tuner with high reflectivity to produce high saturation power at elevated temperature for high-speed data communication application, though other applications are possible.

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels inner, outer, left, right, frontend, backend, top, bottom, have been used for convenience purposes only and are not intended to imply any particular fixed direction. Instead, they are used to reflect relative locations and/or directions between various portions of an object.

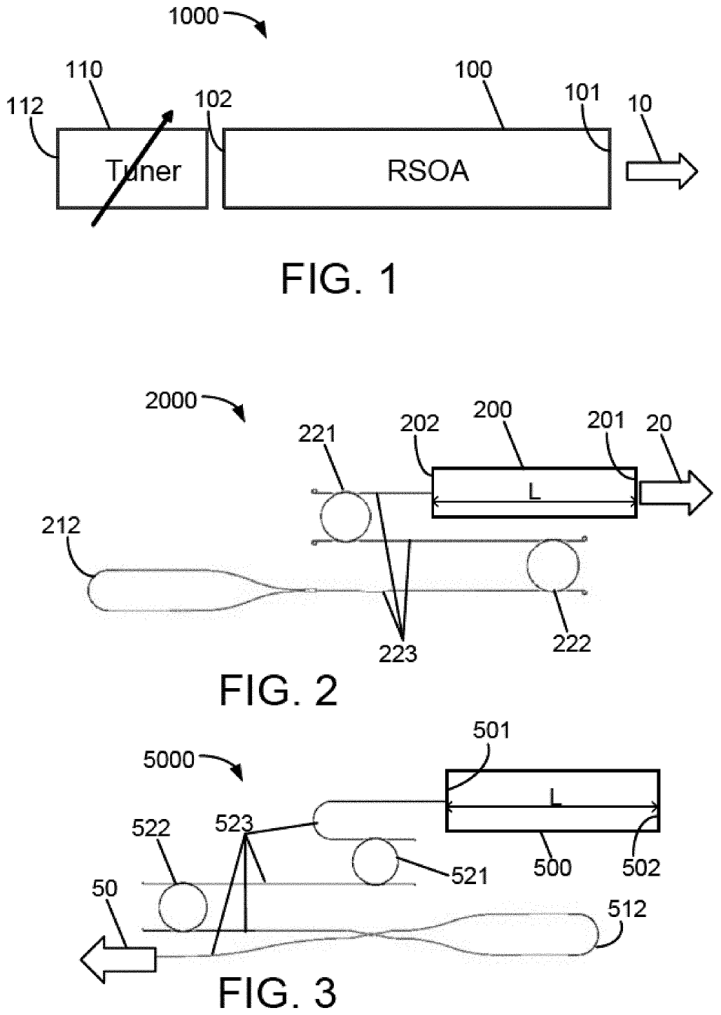

In an aspect, the present disclosure provides a tunable laser having a reflective semiconductor optical amplifier (RSOA) based gain medium with a backend-coupled resonant ring tuner capable of producing high output power at elevated temperature. FIG. 1 is a schematic diagram of a tunable laser device having a gain medium cavity including a backend-coupled wavelength tuner according to an embodiment of the present invention. This diagram is merely an example, which should not unduly limit the scope of the claims. One of ordinary skill in the art would recognize many variations, alternatives, and modifications. As shown, the tunable laser device 1000 includes a semiconductor gain chip 100 having a linear gain medium between a frontend 101 configured as a light output port and a backend 102 coupled to a wavelength tuner 110. Optionally, the semiconductor gain chip 100 is made by semiconductor-based materials configured in multi-quantum-well structure between a facet at the frontend 101 and a facet at the backend 102. The wavelength tuner 110 is configured to receive light from the linear gain medium through the facet of the backend 102 when the linear gain medium 100 excites stimulated emission. This effectively extends the gain medium cavity length from the backend 102 to a reflector 112 of the wavelength tuner 110. Optionally, the wavelength tuner 110 is a wide-band tuner capable of tuning wavelength over entire C band or O band for optical communication applications. Optionally, the wavelength tuner 110 is a silicon-based filter device that is integrated directly into a die of silicon photonics substrate to couple with other silicon photonics devices such as wavelength locker, splitter/combiner, modulator, or photodetector, etc. Optionally, the silicon-based wavelength tuner is integrated in a silicon substrate to couple with the gain chip which is flip-mounted on the same silicon substrate.

Optionally, the linear gain medium of the semiconductor laser chip 100 includes an active region configured in the multi-quantum-well structure. Depending on working wavelength spectrum, different semiconductor materials including one or more compound semiconductors or a combination of InAsP, GaInNAs, GaInAsP, GaInAs, and AlGaInAs may be employed for forming the multi-quantum-well structure sandwiched by a n-type electrode and a p-type electrode to form a diode chip. The active region in multi-quantum-well structure is configured to generate light emission driven by bias current applied across the n-type electrode and the p-type electrode. The linear gain medium also provides a cavity for amplifying light intensity therein. Optionally, for the tunable laser device 1000 the facet at the frontend 101 of the linear gain medium 100 is coated with a low-reflective coating and the facet at the backend 102 is coated with anti-reflective coating. This makes the gain medium a reflective semiconductor optical amplifier (RSOA). The reflector 112 of the wavelength tuner 110 is configured to be with high reflectivity. As the wavelength tuner 110 is coupled to the backend 102, it effectively extends the cavity from the backend 102 to the reflector 112 for the light being tuned in wavelength in the tuner and amplified in intensity in the gain medium. Optionally, the low-reflective coating at the frontend 101 yields a reflectivity in a range from about 1% to about 20%. Preferably, the frontend 101 is designed to serve as a laser output port with low reflectivity less than 8%. The high reflectivity for the reflector 112 in the wavelength tuner 110 can be made as high as possible, e.g., >90% up to high 99%, to enhance laser power efficiency. Additionally, it is found that the longer the length of the linear gain medium, the bigger light power gain is produced by the gain medium. Optionally, the linear gain medium 100 is set its length L between the frontend 101 and the backend 102 to be 1.5 mm or greater to make the laser output power greater than 17 dBm or higher.

FIG. 2 is a schematic diagram of a tunable laser device having a RSOA-based gain medium cavity with high reflectivity achieved through a backend-coupled resonant ring tuner according to an embodiment of the present invention. This diagram is merely an example, which should not unduly limit the scope of the claims. One of ordinary skill in the art would recognize many variations, alternatives, and modifications. As shown, the tunable laser device 2000 includes a diode-based gain chip 200 with a linear gain medium of a length L between a backend 202 coupled to a resonant ring tuner and a frontend configured as a laser output port 20. The tunable laser device 2000 is provided as a specific embodiment of the tunable laser device 1000. Similarly, the gain chip 200 is flip-mounted on a silicon substrate provided in silicon photonics platform. The frontend 201 is configured as a low-reflectivity facet with its reflectivity being controlled within a range of 1% to 20%. Preferably the reflectivity of the frontend facet is kept low about 1% to 8% to make the laser power efficiency high at the output port 20. The backend 202 is coated by an anti-reflective coating to make it substantially transparent for the light emitted in the gain medium to pass through into the resonant ring tuner or allow reflected light from the resonant ring tuner back to the gain medium.

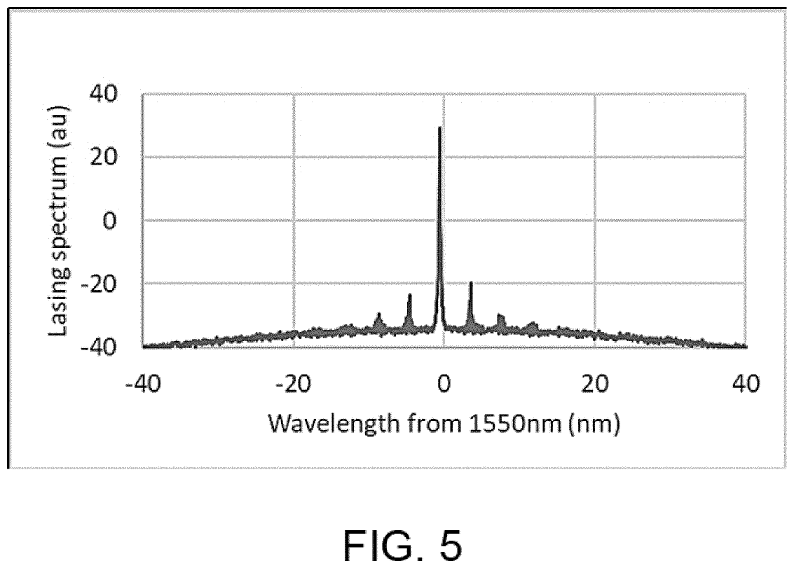

Referring to FIG. 2, the resonant ring tuner is a specific type of the wavelength tuner 110 made in silicon photonics platform. In particular, the resonant ring tuner is made by silicon or silicon nitride wire waveguide in the silicon substrate. One linear section of wire waveguide 223 is coupled to an exit port at the backend 202 of the diode-based gain chip 200 to receive light. The light is guided by the linear section of the wire waveguide 223 to a first ring 221, made by the same wire waveguide in a circular shape, to induce a first resonant frequency shift to the light in the waveguide. Further, the light is guided by another linear section of the wire waveguide 223 to a second ring 222 to induce a second resonant frequency shift to the light in the waveguide. The first ring 221 and the second ring 222 are made with different diameters for generating different phase shift for the light traveling through thereof. In an example, the first ring 221 has a diameter of about 24 μm and the second ring 222 has a diameter slightly bigger at about 25 μm. Furthermore, the light is guided by yet another linear section of the wire waveguide 223 to a reflector 212. The reflector 212 includes a loop of the wire waveguide without external splitting branch to cause the light substantially (>90%) returned back to the in-coming wire waveguide to generate light interference spectrum with a sharp peak at a specific wavelength while all side modes being substantially suppressed or filtered (see FIG. 5 below). The specific wavelength is determined by the difference between the first resonant frequency shift and the second resonant frequency shift which are depended upon the difference in diameters of the first ring and the second ring as well as any phase change around the two rings. The phase change can be caused externally, for example, by adding a heater on top of each ring to change temperature. Thus, the specific peak wavelength in the light interference spectrum can be tuned within a certain tunable range. Optionally, the tunable range of the resonant ring tuner includes entire C-band or O-band, depending on application. Eventually, the light with a specifically tuned wavelength is returned to the gain medium 200. The light intensity is amplified in the gain medium 200 before the laser light is outputted with the tuned wavelength from the output port 20.

Referring to FIG. 2, as the resonant ring tuner is coupled to the backend 202 of the gain chip 200, the reflector 212 can be designed to have high reflectivity near 100% to allow light to fully reflect to the gain medium 200. The light traveling through the resonant ring tuner has relatively low intensity, thus the optical loss in the tuner does not affect the light intensity that much. The reflector 212 with high-reflectivity of the backend-coupled resonant ring tuner effectively extends the laser cavity of the gain medium 200 from the backend 202 to the reflector 212. While, at the same time, the frontend 201 of the gain medium 200 is characterized by a low reflectivity at least <10% or as low as 1%, representing a desired output port reflectivity for the tunable laser device 2000. The lower the output port reflectivity is set, the higher the output power for the tunable laser is produced. Additionally, the laser light with a lower intensity (before amplification in the gain medium) will suffer about 5.5 dB loss by passing though the resonant ring tuner and return to the gain medium 200. After the laser light intensity is amplified by the gain medium 200, the light is directly outputted with a minimum loss through the low-reflectivity output port 20. Thus, this tunable laser design using a RSOA-based gain medium with a backend-coupled resonant ring tuner has low tuner loss effect and can output high-power laser in higher efficiency with a wide-band tunability. In particular, unlike some traditional SOA/RSOA based tunable laser, no second SOA-based gain medium is required as a booster for this high-power tunable laser.

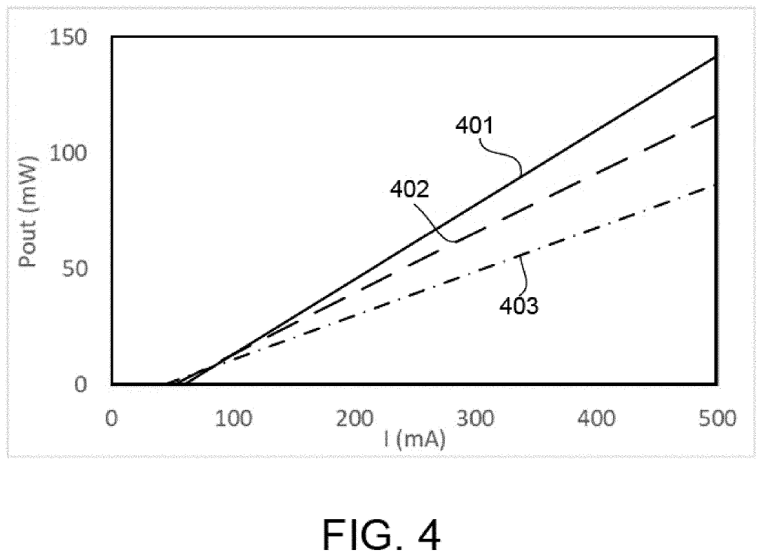

FIG. 4 shows an exemplary plot of light output power of the tunable laser device of FIG. 2 with different frontend reflectivity according to an embodiment of the present invention. As shown, the light output power Pout of the tunable laser device is plotted against driving current I for different cases with different frontend reflectivity values. Referring to FIG. 4, the curve 401 is for a gain medium with the frontend reflectivity being set to 0.05, the curve 402 is for a gain medium with the frontend reflectivity being set to 0.1, and the curve 403 is for a gain medium with the frontend reflectivity being set to 0.2. Apparently FIG. 4 shows that the light output power Pout is monotonically increasing with higher driving current. More importantly, FIG. 4 shows that the gain medium with a low reflectivity can produce much higher output power than the gain medium with a higher reflectivity. The gain medium length should also play a role in light output. Additionally, the longer the gain medium length, the larger the output laser power. Optionally, the linear gain medium 200 is set its length L between the frontend 201 and the backend 202 to be 1.5 mm or greater to make the laser output power greater than 17 dBm or higher.

FIG. 3 shows an alternative design of a tunable laser device 5000 having a RSOA-based gain medium 500 with a frontend-coupled resonant ring tuner. In this design, the resonant ring tuner also is made by Si or SiN-based wire waveguide including two rings 521, 522 of different diameters respectively connected by several linear sections 523 of wire waveguide and a reflector 512. One linear section of the wire waveguide 523 is coupled to a frontend 501 of the gain medium 500. The gain medium 500 generates stimulated light emission which is reflected by a backend facet 502 configured with high reflectivity (>90%). The frontend 501 of the gain medium 500 is coated by anti-reflective coating to allow the light to pass through and enter the resonant ring tuner. Similar to the resonant ring tuner coupled in the tunable laser device 2000, an interference spectrum with a major mode peak at a specific wavelength can be generated in the resonant ring tuner and the peak wavelength can be tuned by tuning temperature around the two rings with different diameters. The reflector 512 includes a loop of the wire waveguide but having a splitting branch to cause part (<20%) of light reflecting backward to induce interference spectrum in the tuner and another part (>80%) of the light outputting via the output port 50. Effectively, the output port 50 is characterized as a low-reflectivity output of the tunable laser device 5000 by the reflector 512 in a range of 3% to 20%.

However, benefit of lowering output port reflectivity at the reflector 512 for enhancing power efficiency of laser output is limited as laser light with amplified intensity passing through the resonant ring tuner will suffer about 5.5 dB tuner loss before being outputted from the output port 50. Thus, the tunable laser device 5000 is relatively poorer in producing laser output power than the tunable laser device 2000 under a same output port reflectivity setting. For example, for a same output port reflectivity set at 0.05, the power gain of tunable laser device 2000 is greater than 2 times than that of tunable laser device 5000. It is also found that the gain medium 200 with a longer length in the tunable laser device 2000 of FIG. 2 is able to produce bigger (>2×) power gain than the gain medium of a same length in the tunable laser device 5000 of FIG. 3.

The advantage of the high-power tunable laser device in silicon photonics platform can also be demonstrated by a side mode suppression ratio (SMSR) of the laser spectrum produced by the tunable laser. FIG. 5 is an exemplary plot of laser spectrum produced by the tunable laser device of FIG. 2 for wavelength around 1550 nm according to an embodiment of the present invention. As shown, the laser spectrum produced by the tunable laser device with the RSOA-based gain medium and a backend-coupled resonant ring tuner gives a major mode peaked at wavelength of about 1550 nm. All side modes are suppressed by a SMSR of about 51 dB as the resonant ring tuner serves as a good filter to eliminate those side modes. When the light is tuned within the resonant ring tuner, light intensity is relatively weak. The filtered light then is reflected back to go through the RSOA-based gain medium 200 and the major mode that already dominates in the spectrum is amplified again, so the SMSR is very high. However, for the tunable laser design in FIG. 3, the light with all modes is weak in intensity as it goes through the resonant ring tuner and is filtered before the light is outputted from the output port 50. The light does not have much reflected by the reflector 512 to get amplified at the gain medium so that the SMSR for the tunable laser device 5000 of FIG. 3 is not that good. This again shows that the tunable laser device of FIG. 2 is a better design than the tunable laser device of FIG. 3 both in laser spectrum SMSR performance and output power efficiency.

While the above is a full description of the specific embodiments, various modifications, alternative constructions and equivalents may be used. Therefore, the above description and illustrations should not be taken as limiting the scope of the present invention which is defined by the appended claims.

1. A high-power tunable laser for outputting wavelength tuned laser light, comprising:
a gain medium configured to receive light, amplify a light intensity of light in the gain medium and emit light having an amplified light intensity, the gain medium configured as a reflective semiconductor optical amplifier (RSOA) having a length extending between a backend and a frontend, the front-end being configured as an output port for outputting light having amplified light intensity relative to received light that is received at the backend; and
a wavelength tuner optically coupled to the backend of the gain medium, the wavelength tuner configured to receive light from the gain medium and tune a wavelength of light from the gain medium, the wavelength tuner having a high-reflectivity reflector configured to reflect the light with a tuned wavelength back to the gain medium the length of the gain medium being dimensioned to amplify light power of light received from the wavelength tuner to output wavelength tune laser light.

2. The high-power tunable laser of claim 1 wherein the gain medium comprises a semiconductor based active region configured in a multi-quantum-well heterostructure configured to generate light emission driven by a bias current applied across n-type and D-type electrodes.

3. The high-power tunable laser of claim 2 wherein the multi-quantum-well heterostructure is made from one or more compound semiconductors selected from InAsP, GaInNAs, GaInAsP, GaInAs, and AlGaInAs.

4. The high-power tunable laser of claim 1, wherein the backend of the RSOA has an anti-reflective coating and the frontend of the RSOA has a reflectivity of less than 8%, and wherein the length between the backend and the frontend is equal to or greater than 1.5 mm.

5. The high-power tunable laser of claim 1 wherein the high-reflectivity reflector in the wavelength tuner is characterized by a reflectivity greater than 90%.

6. The high-power tunable laser of claim 1 wherein the wavelength tuner is configured to tune a wavelength of the light over an entirety of a C band or an O band.

7. The high-power tunable laser of claim 1 wherein the gain medium is disposed in a semiconductor chip mounted on a silicon photonics substrate and the wavelength tuner is a silicon-based filter that is integrated directly into the silicon photonics substrate.

8. The high-power tunable laser of claim 7 wherein the wavelength tuner is comprised of a resonant ring tuner formed from a silicon or silicon nitride based wire waveguide disposed in the silicon photonics substrate.

9. The high-power tunable laser of claim 1 having (i) an output power of greater than 17 dBm without a second SOA-based gain booster and (ii) a side-mode suppression ratio greater than 35 dB.

10. A high-power tunable laser disposed on a silicon photonics platform comprising:
a silicon substrate;
a semiconductor gain chip flip-mounted on the silicon substrate, the semiconductor gain chip comprising a linear gain medium having a partially reflective frontend and a backend exhibiting anti-reflective characteristics, the gain medium being configured to receive light and amplify light intensity of light in the gain medium before outputting the light having amplified intensity, relative to the light received at the backend, through the frontend; and
a resonant ring tuner including a pair of rings with respectively different diameters and a reflector, each ring being comprised of a wire waveguide disposed in the silicon substrate, the resonant ring tuner being configured to (i) optically couple to the backend of the gain medium, the resonant ring tuner having anti-reflective characteristics enabling it to receive light from the linear gain medium and (ii) tune a wavelength of the light before reflecting wavelength tuned light by the reflector back to the linear gain medium.

11. The high-power tunable laser of claim 10 wherein the semiconductor gain chip is a reflective semiconductor optical amplifier chip.

12. The high-power tunable laser of claim 10 wherein the linear gain medium comprises an active region configured as a multi-quantum-well heterostructure for emitting light and a cavity disposed between the frontend and the backend for amplifying light intensity of light emitted by the multi-quantum-well heterostructure.

13. The high-power tunable laser of claim 12 wherein the multi-quantum-well heterostructure is fabricated from one or more semiconductor materials selected from InAsP, GaInNAs, GaInAsP, GaInAs, and AlGaInAs.

14. The high-power tunable laser of claim 10 wherein the partially reflective frontend is configured to be a light output port having a reflectivity of less than 8%.

15. The high-power tunable laser of claim 10 wherein the wire waveguide disposed in the silicon substrate (i) forms the pair of rings, (ii) connects the pair of rings together and to the reflector, and (iii) is a silicon or silicon nitride based waveguide.

16. The high-power tunable laser of claim 10 wherein the reflector in the resonant ring tuner is comprised of a loop formed in the wire waveguide, the loop being absent of an external splitting branch, the loop being configured to return the light to the wire waveguide in a manner corresponding to a reflectivity of at least 90%.

17. The high-power tunable laser of claim 16 wherein the resonant ring tuner is configured to use the pair of rings with different diameters and the reflector to generate an interference spectrum for the light, wherein a major mode wavelength is in a tunable range and side modes are substantially filtered.

18. The high-power tunable laser of claim 17 wherein the loop formed in the wire waveguide of the resonant ring tuner is configured to render the major mode wavelength being tunable in an entirety of a C-band or an O-Band while the side modes are suppressed by >35 dB.

19. The high-power tunable laser of claim 10, wherein the resonant ring tuner is optically coupled to the backend of the linear gain medium to allow the light with amplified intensity to be output directly via the frontend.

20. The high-power tunable laser of claim 1 having an output power of greater than 17 dBm using only a single RSOA.
